(19) United States
(12) Patent Application Publication
(10) Pub. No.: US 2009/0173927 A1
(43) Pub. Date: Jul. 9, 2009

(54) Storage node, phase change memory device and methods of manufacturing and operating the same

(75) Inventors: Cheol-kyu Kim, Seoul (KR); Min-ho Kwon, Seoul (KR); Yoon-ho Khang, Yongin-si (KR); Youn-seon Kang, Seoul (KR); Tae-yon Lee, Seoul (KR); Sung Heo, Busan (KR); Ki-bum Kim, Seoul (KR); Sung-wook Nam, Seoul (KR); Dong-bok Lee, Miryang-si (KR)

Correspondence Address: HARNESS, DICKEY & PIERCE, P.L.C., P.O. BOX 8910, RESTON, VA, 20195, US

(73) Assignees: Samsung Electronics Co., Ltd.; Seoul University Industry Foundation

(21) Appl. No.: 12/232,961

(22) Filed: Sep. 26, 2008

(30) Foreign Application Priority Data
Jan. 9, 2008 (KR) 10-2008-0002636

(51) Int. Cl. H01L 29/02; H01L 21/44

(52) U.S. Cl. 257/2; 438/652; 257/E45.001

(57) ABSTRACT

Provided are a storage node, phase change memory device and methods of manufacturing and operating the same. The storage node may include an electrode, a phase change layer, and an anti-diffusion layer between the electrode and the phase change layer and including a silicide compound. The phase change memory device may include the storage node and a switching device connected to the storage node.

### PRIORITY STATEMENT

This application claims priority under U.S.C. §119 to Korean Patent Application No. 10-2008-0002636, filed on Jan. 9, 2008, in the Korean Intellectual Property Office (KIPO), the entire contents of which are incorporated herein by reference.

### BACKGROUND

1. Field

Example embodiments relate to a storage node, a memory device and methods of manufacturing and operating the same. Other example embodiments relate to a storage node, a phase change memory device and methods of manufacturing and operating the same.

2. Description of the Related Art

A phase change memory device (PRAM) is a type of non-volatile memory device, e.g., flash memory, ferroelectric RAM (FeRAM), and magnetic memory (MRAM). A structural difference between PRAM and other non-volatile memory devices is in the storage node.

A storage node of a PRAM may include a phase change layer as a data storage layer. If a predetermined or given reset voltage is applied to the phase change layer for a relatively short period of time, a part of the phase change layer may be heated above a crystallization temperature and then may be cooled to have an amorphous region. The amorphous region may be changed again into a crystallized region by applying a set voltage to the storage node for a relatively long period of time.

If a resistance of the phase change layer, where an amorphous region exists in the phase change layer, is referred to as a first resistance, and a resistance of the phase change layer, where the entire phase of the phase change layer is in a crystallized state, is referred to as a second resistance, the first resistance may be larger than the second resistance. PRAM may be a memory device recording and reading bit data using the resistance characteristics of a phase change layer with a varying resistance depending on the phase of the phase change layer.

However, in a conventional PRAM, an inter-diffusion of the component materials between a phase change layer and an electrode in contact with the phase change layer may cause a deterioration in the interface conditions between the phase change layer and the electrode, and may cause undesirable phase change properties of the phase change layer and undesirable electrical properties of the electrode. For example, a part of the phase change layer in contact with the electrode (the part hereinafter referred to as “phase change region”) may experience repetitive heating and cooling processes by a voltage that is applied to the electrode.

During this process, an inter-diffusion of materials between the phase change region and the electrode may more easily occur. Accordingly, the compositions of the phase change layer and the electrode may change, as well as the characteristics of the phase change layer, e.g., a crystallizing temperature determining the reset voltage. Therefore, manufacturing a PRAM with improved operation characteristics and reliability using conventional technology may be difficult.

### SUMMARY

Example embodiments provide a storage node and a phase change memory device using phase change layer properties with varying resistance depending on a phase of the phase change layer, and methods of manufacturing and operating the same.

According to example embodiments, a storage node may include an electrode, a phase change layer, and an anti-diffusion layer between the electrode and the phase change layer including a silicide compound.

The silicide compound may include at least one of a silicide, an oxide of the silicide, and a nitride of the silicide. The silicide may be at least one of titanium silicide, tantalum silicide, cobalt silicide, molybdenum silicide, and tungsten silicide. The silicide compound may be expressed as MₓSi_{y}OₐN_{b}, where M is a metal, x and y are real numbers satisfying 0<x<1 and 0<y<1, and a and b are real numbers satisfying 0≦a<1 and 0≦b<1. The metal may include at least one of Ti, Ta, Co, Mo, and W. The electrode may include silicon, and may be a lower electrode. The storage node may further include an upper electrode on the phase change layer. According to example embodiments, a phase change memory device may include the storage node of example embodiments, and a switching device connected to the storage node.

According to example embodiments, a method of manufacturing a storage node may include forming an electrode, forming an anti-diffusion layer including a silicide compound on the electrode; and forming a phase change layer on the anti-diffusion layer.

The silicide compound may include at least one of a silicide, an oxide of the silicide, and a nitride of the silicide. The silicide may be at least one of titanium silicide, tantalum silicide, cobalt silicide, molybdenum silicide, and tungsten silicide. The silicide compound may be expressed as MₓSi_{y}OₐN_{b}, where M is a metal, x and y are real numbers satisfying 0<x<1 and 0<y<1, and a and b are real numbers satisfying 0≦a<1 and 0≦b<1. The metal may include at least one of Ti, Ta, Co, Mo, and W.

The electrode may include silicon, and may be a lower electrode. The method may further include forming an upper electrode on the phase change layer. According to example embodiments, a method of manufacturing a phase change memory device may include manufacturing the storage node according to example embodiments, and connecting a switching device to the storage node.

Forming the anti-diffusion layer may include forming a metal layer on the electrode; and heat-treating the electrode and the metal layer. The electrode may be formed within a contact hole of an interlayer insulating layer, and the metal layer may be formed on the electrode and the interlayer insulating layer. The method may further include, after heat treating the electrode and the metal layer, removing a residual metal layer on the interlayer insulating layer that does not react with the electrode during the heat-treating. The method may further include, after removing the residual metal layer, heat-treating the anti-diffusion layer.

According to example embodiments, a method of operating a phase change memory device may include maintaining a switching element in an on-state, and applying a voltage between an upper electrode and a lower electrode such that current flows through a phase change layer and an anti-diffusion layer, wherein the anti-diffusion layer is between the lower electrode and the phase change layer and includes a silicide compound. The silicide compound may include at least one of a silicide, an oxide of the silicide, and a nitride of the silicide. The silicide may include at least one of titanium silicide, tantalum silicide, cobalt silicide, molybdenum silicide, and tungsten silicide.

### BRIEF DESCRIPTION OF THE DRAWINGS

Example embodiments will be more clearly understood from the following detailed description taken in conjunction with the accompanying drawings. FIGS. 1-5D represent non-limiting, example embodiments as described herein.

FIG. 1 is a cross-sectional view of a phase change memory device (PRAM) according to example embodiments;

FIG. 2 is an AES (auger electron spectroscopy) analysis result of a first sample manufactured according to example embodiments;

FIG. 3 is an AES analysis result of a second sample manufactured according to Comparative Example 1;

FIG. 4 is a graph illustrating current-resistance characteristics of PRAMs according to example embodiments and Comparative Example 2, respectively.

FIGS. 5A to 5D are cross-sectional views illustrating a method of manufacturing the PRAM according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Hereinafter, example embodiments will be described more fully with reference to the accompanying drawings, in which example embodiments are shown. In the drawings, the thicknesses of layers and regions are exaggerated for clarity. Like reference numerals in the drawings denote like elements throughout the description. Example embodiments may, however, be embodied in many different forms and should not be construed as being limited to the embodiments set forth herein; rather, these embodiments may be provided so that this disclosure will be thorough and complete, and will fully convey the concept of example embodiments to those skilled in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

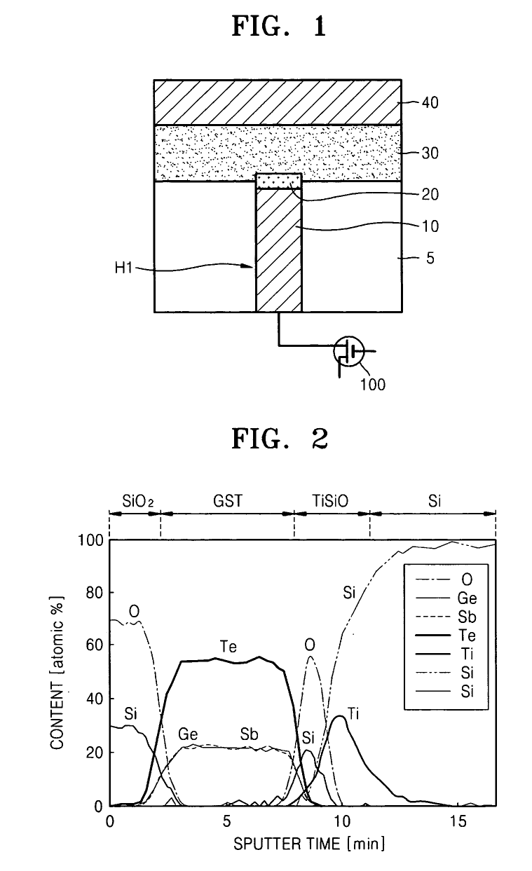

FIG. 1 illustrates a phase change memory device (PRAM) according to example embodiments. Referring to FIG. 1, a phase change layer 30 may be disposed between a lower electrode 10 and an upper electrode 40, and an anti-diffusion layer 20 may be disposed between the lower electrode 10 and the phase change layer 30. The lower electrode 10, the anti-diffusion layer 20, the phase change layer 30 and the upper electrode 40 may form a single storage node.

The lower electrode 10 may be a plug-type electrode disposed within a contact hole H1 of an interlayer insulating layer 5, and a pad-type electrode (not shown) in contact with the lower electrode 10 may be further disposed below the interlayer insulating layer 5. The anti-diffusion layer 20 may be disposed on a top surface of the lower electrode 10, and the phase change layer 30 and the upper electrode 40 may be sequentially disposed on the interlayer insulating layer 5 and the anti-diffusion layer 20. A part of the anti-diffusion layer 20 may be disposed within the contact hole H1, and the rest may protrude above the contact hole H1. However, the anti-diffusion layer 20 may be entirely disposed within or outside the contact hole H1. Accordingly, the height of a top surface of the anti-diffusion layer 20 may be the same as, greater than, or less than a top surface of the interlayer insulating layer 5.

The lower electrode 10 may be a Si-based electrode, and the anti-diffusion layer 20 may include a silicide compound. The silicide compound may be defined as a material including silicides, oxides of the silicides, and nitrides of the silicides. For example, the silicide compound may be expressed as MₓSi_{y}OₐN_{b}, where M is a metal, x and y are real numbers satisfying 0<x<1 and 0<y<1, and a and b are real numbers satisfying 0≦a<1 and 0≦b<1. The M of MₓSi_{y}OₐN_{b} may include at least one of Ti, Ta, Co, Mo, and W. Table 1 below shows the properties of various silicides that may be used in example embodiments.

TABLE 1

| | | | Stable up to | Electrical |
|---|---|---|---|---|
| | Specific | Sintering | temp. below | barrier height |
| | Resistance | Temp. | on Si layer | with respect to |
| Silicides | (μΩcm) | (° C.) | (~° C.) | n-Si layer (eV) |
| TiSi₂(C49) | 60~70 | 500~700 | | |
| TiSi₂(C54) | 13~16 | 700~900 | 900 | 0.58 |
| WSi₂ | 30~70 | 1000 | 1000 | 0.67 |
| Co₂Si | ~70 | 300~500 | | |
| CoSi | 100~150 | 400~600 | | |
| CoSi₂ | 14~20 | 600~800 | 950 | 0.65 |
| MoSi₂ | 40~100 | 800~1000 | 1000 | 0.64 |
| TaSi₂ | 35~55 | 800~1000 | 1000 | 0.59 |

Because a Joule heat generation at the anti-diffusion layer 20 increases as the specific resistance of the anti-diffusion layer 20 increases, the operational current of a memory device may more easily be lowered. Moreover, using a material stable at a melting temperature of the phase change layer 30 (about 600° C.) as the anti-diffusion layer 20 may be advantageous in ensuring reliability.

One of the lower electrode 10 and the upper electrode 40, for example, the lower electrode 10, may be connected to a transistor 100. The transistor 100 may be only an example of a switching device, and may be replaced with other devices having a switching device characteristic, e.g., a diode. A part of the phase change layer 30 in contact with the lower electrode 10 may change its phase, according to the voltage applied between the lower electrode 10 and the upper electrode 40.

The anti-diffusion layer 20 of the PRAM according to example embodiments may play a role in suppressing or preventing an inter-diffusion between materials of the lower electrode 10 and the phase change layer 30. Therefore, the deterioration of characteristics of the phase change layer 30 and the lower electrode 10 may be suppressed or minimized by the anti-diffusion layer 20. Thus, according to example embodiments, a PRAM with improved operational characteristics and reliability may be implemented.

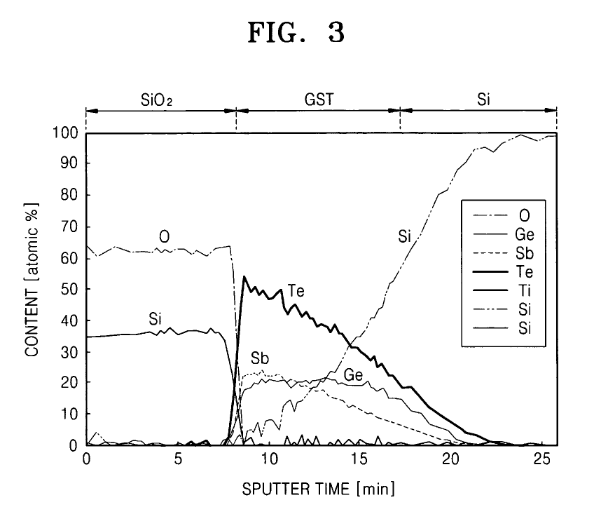

FIG. 2 is a composition analysis result of a first sample manufactured according to example embodiments, and FIG. 3 is a composition analysis result of a second sample manufactured according to Comparative Example 1. The first sample may be a Si/TiSiO/GST/SiO₂ structure where a TiSiO layer, a Ge₂Sb₂Te₅ layer (GST layer), and a SiO₂ layer are sequentially formed on a Si layer, which was annealed at about 500° C. for about 30 minutes, and the second sample may be a Si/GST/SiO₂ structure where a GST layer and a SiO₂ layer are sequentially formed on a Si layer, which was annealed at about 500° C. for about 30 minutes. The TiSiO layer of the first sample corresponds to the anti-diffusion layer 20 of FIG. 1. The composition analysis of the first and second samples was performed using AES (auger electron spectroscopy).

The horizontal axis of FIGS. 2 and 3 represents a sputtering time for etching the first and the second samples, from a surface portion (SiO₂ layer), along a given line, and the vertical axis represents the content (atomic %) of the component materials measured along the given line of the first and the second samples. The first sample, as shown in its corresponding result of FIG. 2, may contain almost no Si within the GST layer, but the second sample, as shown in the corresponding result of FIG. 3, may contains a relatively large amount of Si within the GST layer. This indicates that in the first sample, the diffusion of Si of the Si layer into the GST layer has been suppressed or reduced by the TiSiO layer.

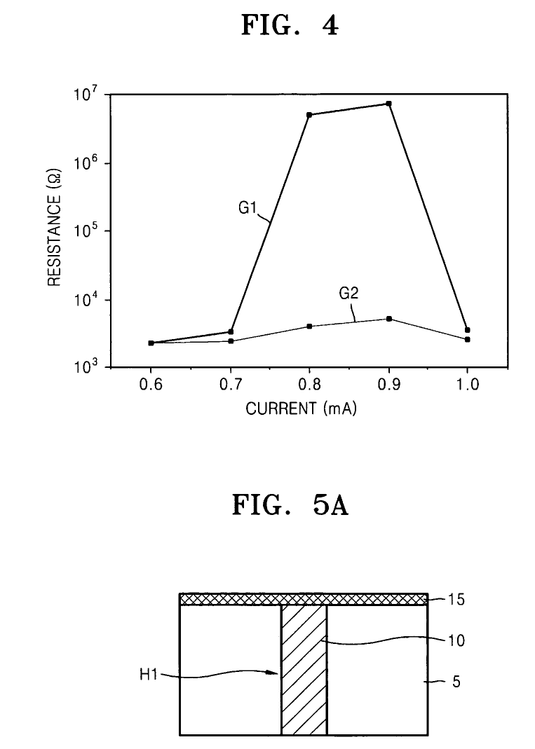

FIG. 4 illustrates the current-resistance characteristics of PRAMs according to example embodiments and to Comparative Example 2, respectively. In FIG. 4, a first graph G1 is a result corresponding to the PRAM having a structure as the one of FIG. 1, and a second graph G2 is a result corresponding to the PRAM according to Comparative Example 2. The PRAM according to Comparative Example 2 has a structure of an anti-diffusion layer 20 extended between the interlayer insulating layer 5 and the phase change layer 30 in FIG. 1.

The first graph G1 of FIG. 4 shows relatively great fluctuation of resistance with respect to current, but the second graph G2 shows almost no fluctuation of resistance with respect to current. This indicates that the PRAM having the structure of FIG. 1 has resistance variation characteristics required by the PRAM, but in the structure of an anti-diffusion layer 20 extended between the interlayer insulating layer 5 and the phase change layer 30 (Comparative Example 2), the PRAM may not exhibit resistance variation characteristics. For example, when the anti-diffusion layer 20 with relatively low electrical resistance is extended between the interlayer insulating layer 5 and the phase change layer 30, an unwanted current path may be formed, thereby, making programming difficult.

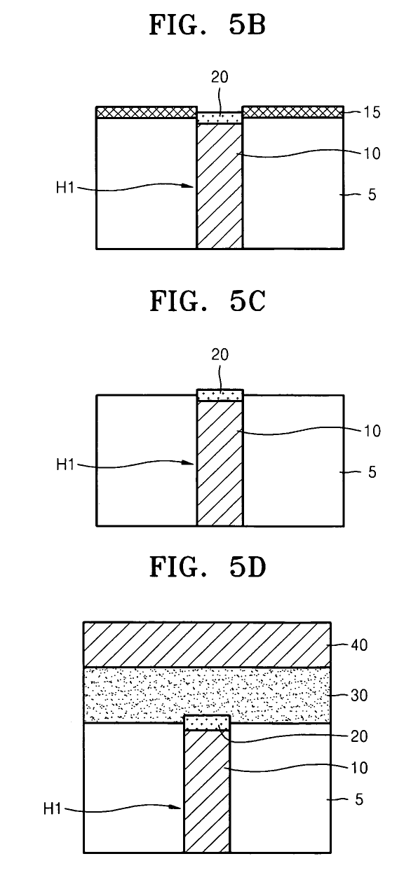

FIGS. 5A to 5D illustrates a method of manufacturing the PRAM according to example embodiments. Referring to FIG. 5A, a lower electrode 10 may be formed within a contact hole H1 of an interlayer insulating layer 5. The lower electrode 10 may be a Si-based electrode, and may be formed to be electrically connected to a predetermined or given switching device (not shown). A metal layer 15 may be formed on the interlayer insulating layer 5 and the lower electrode 10. The metal layer 15 may be formed using PVD (physical vapor deposition), CVD (chemical vapor deposition) or ALD (atomic layer deposition), and may include at least one of Ti, Ta, Co, Mo and W.

The lower electrode 10 and the metal layer 15 may be heat treated (First heat treatment) so that the lower electrode 10 and the metal layer 15 react. The first heat treatment may be carried out at a temperature of about 300 to 1000° C. under a gas atmosphere of Ar, N₂, O₂, SiH₄ or SiH₂, and may be performed using RTA (rapid thermal annealing). As a result of the first heat treatment, as shown in FIG. 5B, an anti-diffusion layer 20 including a silicide compound may be formed on the lower electrode 10. The portion of the metal layer 15 that did not react with the lower electrode 10 during the first heat treatment may remain on the interlayer insulating layer 5.

The metal layer 15, not removed during the first heat treatment, may be removed by a wet cleaning process. For the wet cleaning process, SC1 (Standard Cleaning-1), which is a mixed aqueous solution of ammonia and hydrogen peroxide, may be used as a cleaning solution. The resulting product of the removed non-reacting metal layer 15 is shown in FIG. 5C.

A heat treatment (second heat treatment) may be performed on the anti-diffusion layer 20. The second heat treatment may be performed, similar to the first heat treatment, at a temperature of about 300 to 1000° C. under a gas atmosphere of Ar, N₂, O₂, SiH₄ or SiH₂, and may be performed using RTA (rapid thermal annealing). Due to the second heat treatment, at least a part of the anti-diffusion layer 20 may be nitrified or oxidized, the phase of the anti-diffusion layer 20 may be better stabilized, or the surface of the anti-diffusion layer 20 may be modified. For example, the characteristics of the anti-diffusion layer 20 may be enhanced through the second heat treatment. However, the optional second heat treatment may not be performed.

Referring to FIG. 5D, a phase change layer 30 and an upper electrode 40 may be sequentially formed on the interlayer insulating layer 5 and the anti-diffusion layer 20. In the method of manufacturing described with reference to FIGS. 5A to 5D, the anti-diffusion layer 20 may be self-aligned on the lower electrode 10, and thus, a problem of misalignment of the anti-diffusion layer 20 with the lower electrode 10 may be prevented or reduced.

While example embodiments have been particularly shown and described in detail, the embodiments should be interpreted not as limiting the scope of example embodiments. For example, it will be understood by one of ordinary skill in the art that various changes in form and details of the memory device of FIG. 1 may be made, and the method of manufacturing shown in FIGS. 5A to 5D may also be modified without departing from the spirit and scope of the following claims.

What is claimed is:

1. A storage node comprising:
an electrode;
a phase change layer; and
an anti-diffusion layer between the electrode and the phase change layer including a silicide compound.

2. The storage node of claim 1, wherein the silicide compound includes at least one of a silicide, an oxide of the silicide, and a nitride of the silicide.

3. The storage node of claim 2, wherein the silicide includes at least one of titanium silicide, tantalum silicide, cobalt silicide, molybdenum silicide, and tungsten silicide.

4. The storage node of claim 1, wherein the electrode includes silicon.

5. The storage node of claim 1, wherein the electrode is a lower electrode.

6. The storage node of claim 5, further comprising:
an upper electrode on the phase change layer.

7. A phase change memory device comprising:
the storage node of claim 1; and
a switching device connected to the storage node.

8. A method of manufacturing a storage node comprising:
forming an electrode;
forming an anti-diffusion layer, including a silicide compound, on the electrode; and
forming a phase change layer on the anti-diffusion layer.

9. The method of claim 8, wherein the silicide compound includes at least one of a silicide, an oxide of the silicide, and a nitride of the silicide.

10. The method of claim 8, wherein the silicide includes at least one of titanium silicide, tantalium silicide, cobalt silicide, molybdenum silicide, and tungsten silicide.

11. The method of claim 8, wherein the electrode includes silicon.

12. The method of claim 8, wherein the electrode is a lower electrode.

13. The method of claim 12, further comprising:
forming an upper electrode on the phase change layer.

14. A method of manufacturing a phase change memory device comprising:
manufacturing the storage node according to claim 8; and
connecting a switching device to the storage node.

15. The method of claim 8, wherein forming the anti-diffusion layer comprises:
forming a metal layer on the electrode; and
heat-treating the electrode and the metal layer.

16. The method of claim 15, wherein the electrode is formed within a contact hole of an interlayer insulating layer, and
the metal layer is formed on the electrode and the interlayer insulating layer.

17. The method of claim 16, after heat treating the electrode and the metal layer, further comprising:
removing a residual metal layer on the interlayer insulating layer that does not react with the electrode during the heat-treating.

18. The method of claim 17, after removing the residual metal layer, further comprising:
heat-treating the anti-diffusion layer.
